(19) United States
(12) Patent Application Publication
(10) Pub. No.: US 2005/0285111 A1
(43) Pub. Date: Dec. 29, 2005

(54) Semiconductor apparatus and manufacturing method thereof

(76) Inventor: Shinzo Tsuboi, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/066,266

(22) Filed: Feb. 28, 2005

(30) Foreign Application Priority Data
Jun. 28, 2004 (JP) 2004-189501

(51) Int. Cl. H01L 29/10

(52) U.S. Cl. 257/66

(57) ABSTRACT

A semiconductor apparatus in which a substantially entire channel region being a partial depletion type comprises a semiconductor layer provided on one surface side of a substrate, a channel region having a first electroconductive type provided in the semiconductor layer, a high-concentration diffusion region having a second electroconductive type provided in the semiconductor layer being adjacent to the channel region, facing both sides of the channel region, and being separated, a body terminal having the first electroconductive type which is connected with the channel region to fix a potential of the channel region, an insulator provided on the channel region, a gate electrode provided on the insulator to cover the channel region, and a channel edge portion disposed at an end portion of the channel region and also at an end portion of the semiconductor layer, and containing an impurity having the first electroconductive type therein.

### CROSS-REFERENCE TO RELATED APPLICATIONS

This application is based upon and claims the benefit of priority from prior Japanese Patent Application No. 2004-189501, filed Jun. 28, 2004, the entire contents of which are incorporated herein by reference.

### BACKGROUND OF THE INVENTION

1. Field of the Invention

The present invention relates to a semiconductor apparatus and a manufacturing method thereof, and more particularly to a thin film transistor used in a liquid crystal display apparatus and a manufacturing method thereof.

2. Description of the Related Art

A so-called thin film transistor (TFT) including a field effect transistor formed in a semiconductor layer provided above a substrate is used as a switching device which drives, e.g., a liquid crystal display apparatus for a display operation.

FIGS. 12A and 12B show an example of a thin film transistor 1 according to a prior art. FIG. 12A is a perspective view, and FIG. 12B is a cross-sectional view in a channel width direction taken along a cutting plane line 12B-12B depicted in FIG. 12A. A semiconductor layer 14 is formed on a substrate 10, e.g., a glass substrate, through an underlying insulator 12, e.g., a silicon oxide film (SiO₂). The semiconductor layer 14 is, e.g., a polycrystal silicon layer having larger crystal grains. A thin film transistor 1 including, e.g., a channel region 18, a source 28 and a drain 30, a gate insulator 34 formed on the channel region 18, and a gate electrode 36 formed on the gate insulator 34 is formed to the semiconductor layer 14. Such thin film transistor 1 having the gate electrode 36 formed on the semiconductor layer 14 is referred as a top gate type thin film transistor. In the example, a substrate having the semiconductor layer 14 of 200 nm in thickness (body film thickness) is used.

In the thin film transistor 1, as shown in FIG. 12B, a side wall surface the body at each end in a cross section of the channel region 18 in the channel width direction has a tapered shape rather than a perpendicular shape (see, e.g., U.S. Pat. No. 5,739,574), and the channel region 18 (9 in the USP mentioned above, and the same hereinafter) comprises a flat channel portion 19 and a tapered portion 20 (13a). In the above-described U.S. Patent, the thin film transistor 1 is designed to have tapered portions 20 (mesas 13a) and form a gate oxide film 34 (21, 18) thicker than that on the flat portion 19 (9) to each tapered portion 20 (13a), thus an electric field concentration at each tapered portion 20 (13a) is alleviated.

However, it is preferable for each end portion of the channel region 18 in the thin film transistor 1 to have a perpendicular shape in order to advance a miniaturization. In reality, however, the tapered portion 20 is unavoidably generated at each end portion of the channel region 18 in a current manufacturing process, and a taper angle of the end portion cannot be controlled to a fixed value within a substrate 10 or between substrates 10. That is, the taper angle at each end portion has variations due to variations in the manufacturing process, and it has been revealed that such variations in taper angle affect characteristics of the thin film transistor 1, such as a threshold value and sub-threshold characteristics. In particular, when the thin film transistor 1 is used as a partial depletion type transistor, it has become clear that an influence of such variations is considerable. In the partial depletion type transistor, a depletion layer is not formed to an entire film thickness (body film thickness) of the semiconductor layer in the channel region 18 but the depletion layer is formed in a part of the film thickness in operation. The partial depletion type transistor can improve a punch-through breakdown voltage as compared with a full depletion type transistor, which is advantageous for a high-breakdown voltage transistor and/or the miniaturization.

FIG. 13 shows an example of drain current-gate voltage (I-V) characteristics of a partial depletion type n channel thin film transistor 1 according to the prior art. A horizontal axis represents a gate voltage, and a vertical axis represents a drain current. Although the drain current increases as the gate voltage becomes larger from approximately −1V, a “bulge” where a curve is distorted before saturation is recognized, as shown surrounded by a circle in the drawing. The bulge is generated due to existence of the tapered portion 20. That is, as the gate voltage increases in a positive direction, a depletion layer is formed in the channel region 18, and the drain current starts flowing. As the gate voltage increases further, a depth of the depletion layer becomes larger in the flat channel portion 19, and then the drain current becomes larger. In the tapered portion 20, however, since a thickness of the semiconductor layer 14 varies from 0 to a body film thickness, in a part of the tapered portion 20 where the thickness of the semiconductor layer 14 is thin, the entire thickness serves as the depletion layer with a lower gate voltage. That is, the tapered potion 20 is fully depleted, and the depletion layer does not expand any further. As a result, a bulge is generated in the I-V characteristics as shown in FIG. 13.

When an impurity concentration in the channel region 18 is high, or when the body film thickness is thicker than the depth of the depletion layer like an example where the gate voltage is low, a partial depletion type transistor is formed. FIG. 14 is a view showing a relationship between an impurity concentration in the channel region 18 and a maximum depletion layer depth. In other words, this is a view showing a boundary between the full depletion type and the partial depletion type. In FIG. 14, the full depletion type (FD) is formed below the curve, and the partial depletion type (PD) is formed above the curve. For example, when an impurity concentration in the channel region 18 is 1×10¹⁷ atoms/cm³, the maximum depletion layer depth is approximately 100 nm. In this case, if the body film thickness is 200 nm, the flat channel portion 19 is of the partial depletion type. However, a part of the tapered portion 20 where the film thickness of the semiconductor layer is less than 100 nm, the full depletion type is realized. In the thin film transistor, when both the full depletion type and partial depletion type region coexist in two regions of the body where the body film thickness with less than 100 nm and the thickness with not less than 100 nm, it has been revealed that such existence is a factor to cause variations in the threshold value or sub-threshold characteristics.

As described above, in the thin film transistor, it is important to control each end portion of the channel region 18, i.e., each tapered portion 20, in order to stabilize the characteristics of the device and improve the reliability. U.S. Pat. No. 6,184,556 B1 discloses a semiconductor apparatus which improves a breakdown voltage between a source and a drain and achieves both the high reliability and the high mobility even if a substrate potential is a floating potential. The semiconductor apparatus has a pinning region which prevents a depletion layer forming a channel from extending to each end portion of a channel region. An impurity which gives an electroconductive type opposite to that of the source and the drain is doped in the pinning region. Further, U.S. Pat. No. 6,753,549 B2 discloses setting an angle of a tapered portion to 60° or above in order to suppress irregularities in characteristics of a thin film transistor, giving insulation properties to the tapered portion, or a technique of doping in the tapered portion an impurity which gives an electroconductive type opposite to that of a source and a drain. Furthermore, U.S. Patent Application No. 2001/0036710 A1 discloses a technique which controls an angle of a tapered portion by LOCOS (local oxidation of silicon). However, these patents do not describe about controlling a substrate potential.

In order to solve the above-described problems, there is a need for a semiconductor apparatus and its manufacturing method which can control a substrate potential, form a substantially entire channel region as a partial depletion type irrespective of a size of a taper angle of an end portion of the channel region, and improve irregularities in characteristics of a thin film transistor caused due to existence of both a full depletion type and a partial depletion type region.

### BRIEF SUMMARY OF THE INVENTION

The above-described problems can be solved by a semiconductor apparatus and its manufacturing method according to the invention set forth below.

According to one aspect of the present invention, a semiconductor apparatus comprises: a semiconductor layer provided on one surface side of a substrate; a channel region having a first electroconductive type provided in the semiconductor layer; a high-concentration diffusion region having a second electroconductive type provided in the semiconductor layer being adjacent to the channel region, facing both sides of the channel region, and being separated; a body terminal having the first electroconductive type which is connected with the channel region to fix a potential of the channel region; an insulator provided on the channel region; a gate electrode provided on the insulator to cover the channel region; and a channel edge portion disposed at an end portion of the channel region and also at an end portion of the semiconductor layer, and containing an impurity having the first electroconductive type therein.

According to another aspect of the present invention, a semiconductor apparatus comprises: a semiconductor layer provided on one surface side of a substrate; a channel region having a first electroconductive type provided in the semiconductor layer; a low-concentration diffusion region having a second electroconductive type provided in the semiconductor layer being adjacent to the channel region, facing both sides of the channel region, and being separated; a high-concentration diffusion region having the second electroconductive type provided in the semiconductor layer on an outer side of each low-concentration diffusion region; a body terminal having the first electroconductive type which is connected with the channel region to fix a potential of the channel region; an insulator provided on the channel region; a gate electrode provided on the insulator to cover the channel region; and a channel edge portion disposed at an end portion of the channel region and also at an end portion of the semiconductor layer, and containing an impurity having the first electroconductive type therein.

According to still another aspect of the present invention, a semiconductor apparatus comprises: a semiconductor layer provided on one surface side of a substrate; and first and second semiconductor devices provided in the semiconductor layer, the first semiconductor device comprising: a first channel region having a first electroconductive type provided in the semiconductor layer; a first high-concentration diffusion region having a second electroconductive type provided in the semiconductor layer being adjacent to the first channel region, facing both sides of the channel region, and being separated; a first body terminal having a first electroconductive type which is connected with the first channel region to fix a potential of the first channel region; a first insulator provided on the first channel region; a first gate electrode provided on the first insulator to cover the first channel region; and a first channel edge portion disposed at an end portion of the first channel region and also at an end portion of the semiconductor layer, and containing an impurity having the first electroconductive type therein, the second semiconductor device comprising: a second channel region having the second electroconductive type provided in the semiconductor layer; a second high-concentration diffusion region having the first electroconductive type provided in the semiconductor layer being adjacent to the second channel region, facing both sides of the channel region, and being separated; a second body terminal having the second electroconductive type which is connected with the second channel region to fix a potential of the second channel region; a second insulator provided on the second channel region; a second gate electrode which is provided on the second insulator and covers the second channel region; and a second channel edge portion disposed at an end portion of the second channel region and also at an end portion of the semiconductor layer, and containing an impurity having the second electroconductive type therein.

According to still another aspect of the present invention, a semiconductor apparatus comprises: a semiconductor layer provided on one surface side of a substrate; and first and second semiconductor devices provided in the semiconductor layer, the first semiconductor device comprising: a first channel region having a first electroconductive type provided in the semiconductor layer; a first low-concentration diffusion region having a second electroconductive type provided in the semiconductor layer being adjacent to the first channel region, facing both sides of the first channel region, and being separated; a first high-concentration diffusion region having the second electroconductive type provided in the semiconductor layer on an outer side of each first low-concentration diffusion region; a first body terminal having a first electroconductive type connected with the first channel region to fix a potential of the first channel region; a first insulator provided on the first channel region; a first gate electrode provided on the first insulator to cover the first channel region; and a first channel edge portion disposed at an end portion of the first channel region and also at an end portion of the semiconductor layer, and containing an impurity having the first electroconductive type therein, the second semiconductor device comprising: a second channel region having the second electroconductive type provided in the semiconductor layer; a second low-concentration diffusion region having the first electroconductive type provided in the semiconductor layer being adjacent to the second channel region, facing both sides of the second channel region, and being separated; a second high-concentration diffusion region having the first electroconductive type provided in the semiconductor layer on an outer side of each second low-concentration diffusion region; a second body terminal having the second electroconductive type which is connected with the second channel region to fix a potential of the second channel region; a second insulator provided on the second channel region; a second gate electrode which is provided on the second insulator and covers the second channel region; and a second channel edge portion disposed at an end portion of the second channel region and also at an end portion of the semiconductor layer, and containing an impurity having the second electroconductive type therein.

According to still another aspect of the present invention, a semiconductor apparatus comprises: a semiconductor layer provided on one surface side of a substrate; a channel region having a first electroconductive type provided in the semiconductor layer; a high-concentration diffusion region having a second electroconductive type provided in the semiconductor layer being adjacent to the channel region, facing both sides of the channel region, and being separated; a body terminal having the first electroconductive type which is connected with the channel region to fix a potential of the channel region; an insulator provided on the channel region; a gate electrode provided on the insulator to cover the channel region; and a channel edge portion disposed at an end portion of the channel region and also at an end portion of the semiconductor layer, and being substantially insulative.

According to still another aspect of the present invention, a semiconductor apparatus comprises: a semiconductor layer provided on one surface side of a substrate; a channel region having a first electroconductive type provided in the semiconductor layer; a low-concentration diffusion region having a second electroconductive type provided in the semiconductor layer being adjacent to the channel region, facing both sides of the channel region, and being separated; a high-concentration diffusion region having the second electroconductive type provided in the semiconductor layer on an outer side of each low-concentration diffusion region; a body terminal having the first electroconductive type which is connected with the channel region to fix a potential of the channel region; an insulator provided on the channel region; a gate electrode provided on the insulator to cover the channel region; and a channel edge portion disposed at an end portion of the channel region and also at an end portion of the semiconductor layer, and being substantially insulative.

According to further aspect of the present invention, a semiconductor apparatus manufacturing method comprises: forming a device region having a first electroconductive type by patterning a semiconductor film formed on one surface side of a substrate; forming a gate insulator on the device region; forming a gate electrode on the gate insulator by covering a part of the device region; forming a high-concentration diffusion region having a second electroconductive type in the device region adjacent to an outer side of the gate electrode; forming a body terminal having the first electroconductive type in the device region on the outer side of the gate electrode which is also a region different from the low-concentration diffusion region and the high-concentration diffusion region; and adding an impurity having the first electroconductive type into an end portion of the device region covered with the gate electrode which is a region excluding a part in contact with the high-concentration diffusion region and body terminal.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIGS. 1A and 1B are views illustrating an example of a thin film transistor according to a first embodiment of the present invention, in which FIG. 1A is a plan view, and FIG. 1B is a cross-sectional view in a channel width direction taken along a cutting plane line 1B-1B in FIG. 1A;

FIGS. 2A and 2B are process sectional views illustrating an example of a thin film transistor manufacturing method according to the first embodiment, in which FIG. 2A is a cross-sectional view in a channel length direction taken along a cutting plane line 2A-2A in FIG. 1A, and FIG. 2B is a cross-sectional view in a channel width direction taken along a cutting plane line 1B-1B in FIG. 1A;

FIGS. 3A and 3B are process sectional views illustrating the thin film transistor manufacturing method according to the first embodiment following FIGS. 2A and 2B, in which FIG. 3A is a cross-sectional view in the channel length direction taken along the cutting plane line 2A-2A in FIG. 1A, and FIG. 3B is a cross-sectional view in the channel width direction taken along the cutting plane line 1B-1B in FIG. 1A;

FIGS. 4A and 4B are process sectional views illustrating a thin film transistor manufacturing method according to the first embodiment following FIGS. 3A and 3B, in which FIG. 4A is a cross-sectional view in the channel length direction taken along the cutting plane line 2A-2A in FIG. 1A, and FIG. 4B is a cross-sectional view in the channel width direction taken along the cutting plane line 1B-1B in FIG. 1A;

FIGS. 5A and 5B are process sectional views illustrating the thin film transistor manufacturing method according to the first embodiment following FIGS. 4A and 4B, in which FIG. 5A is a cross-sectional view in the channel length direction taken along the cutting plane line 2A-2A in FIG. 1A, and FIG. 5B is a cross-sectional view in the channel width direction taken along the cutting plane line 1B-1B in FIG. 1A;

FIGS. 6A and 6B are process sectional views illustrating the thin film transistor manufacturing method according to the first embodiment following FIGS. 5A and 5B, in which FIG. 6A is a cross-sectional view in the channel length direction taken along the cutting plane line 2A-2A in FIG. 1A, and FIG. 6B is a cross-sectional view in the channel width direction taken along the cutting plane line 1B-1B in FIG. 1A;

FIGS. 7A and 7B are process sectional views illustrating the thin film transistor manufacturing method according to the first embodiment following FIGS. 6A and 6B, in which FIG. 7A is a cross-sectional view in the channel length direction taken along the cutting plane line 2A-2A in FIG. 1A, and FIG. 7B is a cross-sectional view in the channel width direction taken along the cutting plane line 1B-1B in FIG. 1A;

FIG. 8 is a view showing an example of drain current-gate voltage characteristics of the thin film transistor according to the first embodiment;

FIGS. 9A, 9B and 9C are views illustrating an example of a thin film transistor according to a modification of the first embodiment, in which FIG. 9A is a plan view, FIG. 9B is a cross-sectional view in the channel width direction taken along a cutting plane line 9B-9B in FIG. 9A, and FIG. 9C is a cross-sectional view in the channel length direction taken along a cutting plane line 9C-9C in FIG. 9A;

FIG. 10 is a view showing an example of drain current-gate voltage characteristics of the thin film transistor according to the modification of the first embodiment;

FIGS. 11A and 11B are views illustrating an example of a thin film transistor according to a second embodiment, in which FIG. 11A is a plan view, and FIG. 11B is a cross-sectional view in the channel width direction taken along a cutting plane line 11B-11B in FIG. 11A;

FIGS. 12A and 12B are views illustrating a conventional thin film transistor, in which FIG. 12A is a perspective view, and FIG. 12B is a cross-sectional view in the channel width direction taken along a cutting plane line 12B-12B in FIG. 12A;

FIG. 13 is a view showing an example of drain current-gate voltage characteristics of the conventional thin film transistor; and

FIG. 14 is a view showing a relationship between a body impurity concentration and a maximum depletion layer depth in a thin film transistor.

### DETAILED DESCRIPTION OF THE INVENTION

Embodiments according to the present invention will now be described hereinafter in detail with reference to the accompanying drawings. In the drawings, like reference numerals denote like or corresponding parts.

### First Embodiment

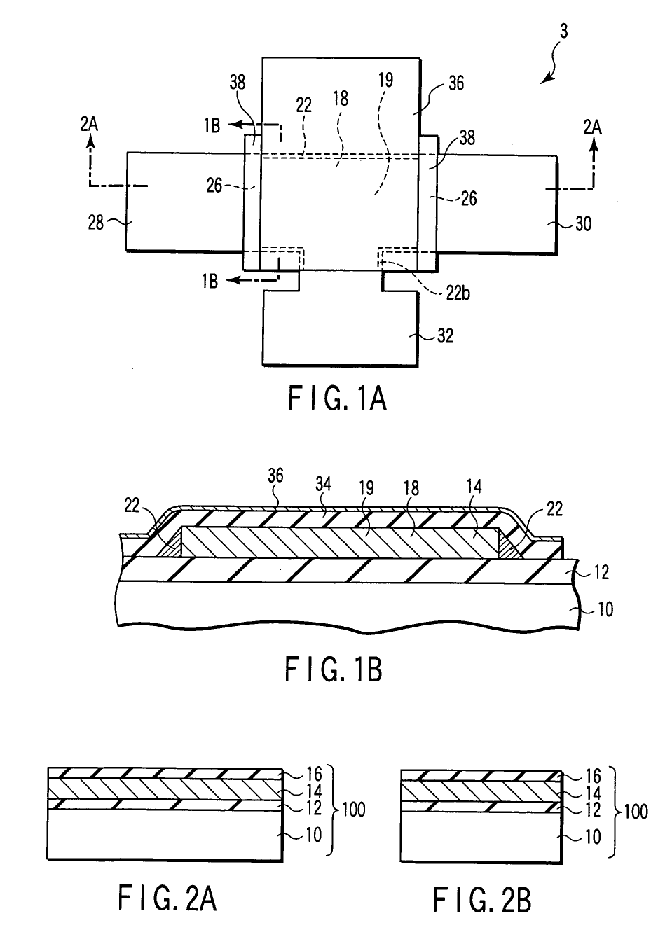

FIG. 1 shows an example of a top gate type thin film transistor 3 according to a first embodiment. FIG. 1A is a plan view, and FIG. 1B is a cross-sectional view in a channel width direction taken along a cutting plane line 1B-1B in FIG. 1A. A semiconductor layer 14 is formed on a support substrate 10, e.g., a glass substrate, through an underlying insulator 12, e.g., a silicon oxide film. The semiconductor layer 14 is processed by etching into a region where a device is formed. A thin film transistor 3 having a body terminal structure is formed in the semiconductor layer 14. The thin film transistor 3 having the body terminal structure comprises, e.g., a channel region 18 formed in the semiconductor layer 14, a source 28 and a drain 30, a body terminal 32, a gate insulator 34 formed on the channel region 18, a gate electrode 36 formed on the gate insulator 34, and others. The body terminal 32 is used to fix a potential of the channel region 18, and stabilizes characteristics of the thin film transistor 3. FIG. 1B shows a cross-sectional view of the thin film transistor 3 in a channel width direction taken along a cutting plane line 1B-1B in FIG. 1A. The channel region 18 formed in the semiconductor layer 14 comprises channel edge portions 22 having a tapered shape and a flat channel portion 19 having a flat shape. An electroconductive impurity having different type from that of the source 28 and the drain 30 is doped to each channel edge portion 22, and an impurity concentration is controlled to a predetermined value. Moreover, it is preferable to control an impurity concentration in the channel edge portion denoted by 22b in FIG. 1A, i.e., an end portion of the semiconductor region 14 at a part drawing the body terminal 32 from the channel region 18, which is also a tapered portion and a part covered with the gate electrode 36 like the channel edge portion 22. By controlling the impurity concentrations in the channel edge portions 22 and 22b in this manner, manufacturing variations in the thin film transistor 3 can be reduced, a yield can be improved, and the characteristics of the thin film transistor 3 can be stabilized.

A manufacturing process of the thin film transistor 3 will now be described with reference to FIGS. 2A and 2B to FIGS. 7A and 7B taking an n channel transistor as an example. In FIGS. 2A and 2B through FIGS. 7A and 7B, each figure A is a cross-sectional view in a channel length direction which is taken along the cutting plane line 2A-2A in FIG. 1A and orthogonal to FIG. 1B, and each figure B is a cross-sectional view in the channel width direction taken along the cutting plane line 1B-1B in FIG. 1A.

(1) First, a semiconductor substrate 100 which is a starting material of the thin film transistor 3 is formed. As shown in FIGS. 2A and 2B, the underlying insulator 12, e.g., a silicon oxide film, is formed on the support substrate 10, e.g., a glass substrate, by plasma CVD, for example. The semiconductor layer 14, e.g., an amorphous silicon film, is formed on the underlying insulator 12 by plasma CVD. A cap insulator 16, e.g., a silicon oxide film, is formed on a surface of the semiconductor layer 14 by plasma CVD. Then, a laser light having a desired light intensity distribution is irradiated to the semiconductor layer 14 through the cap insulator 16 by a crystallization apparatus (not shown) so that the semiconductor layer 14 is crystallized into a semiconductor film including large crystal grains. The laser light is an energy light obtained by homogenizing, e.g., an excimer laser light, to provide a uniform light intensity and forming a light intensity distribution by phase modulation using a phase shifter. In this manner, the semiconductor substrate 100 is formed.

As the support substrate 10, it can be used, e.g., a glass substrate, a quartz substrate, a semiconductor substrate such as silicon, a plastic substrate and a ceramic substrate. The underlying insulator 12 is a film which prevents the impurity from the underlying substrate 10 from being diffused in the semiconductor layer 14 and has a thermal storage effect in the crystallization process and, e.g., a silicon oxide film (an SiO₂ film) or a silicon nitride film (an SiN film) can be used as the underlying insulator 12.

The semiconductor layer 14 is a film in which the thin film transistor 3 is formed, and it can be used a silicon film, e.g., an amorphous silicon film or a polycrystal silicon film, crystallizing the film into a polycrystal film having larger crystal grains by any crystallization method. In the crystallization, an impurity (a dopant), e.g., boron, can be doped in order to adjust a threshold value of the thin film transistor 3. The semiconductor layer 14 is a crystallized silicon layer, and its impurity concentration is, e.g., 2×10¹⁵ atoms/cm³ to 1×10¹⁸ atoms/cm³. The semiconductor layer 14 used in this embodiment has a thickness of 200 nm and an impurity concentration of 1×10¹⁷ atoms/cm³.

As the cap insulator 16, for example, an SiO₂ film or an SiN film can be used. The cap insulator 16 is a film having a function which stores heat given by irradiating the laser light in the crystallization process, and it is, e.g., an SiO₂ film or an SiN film.

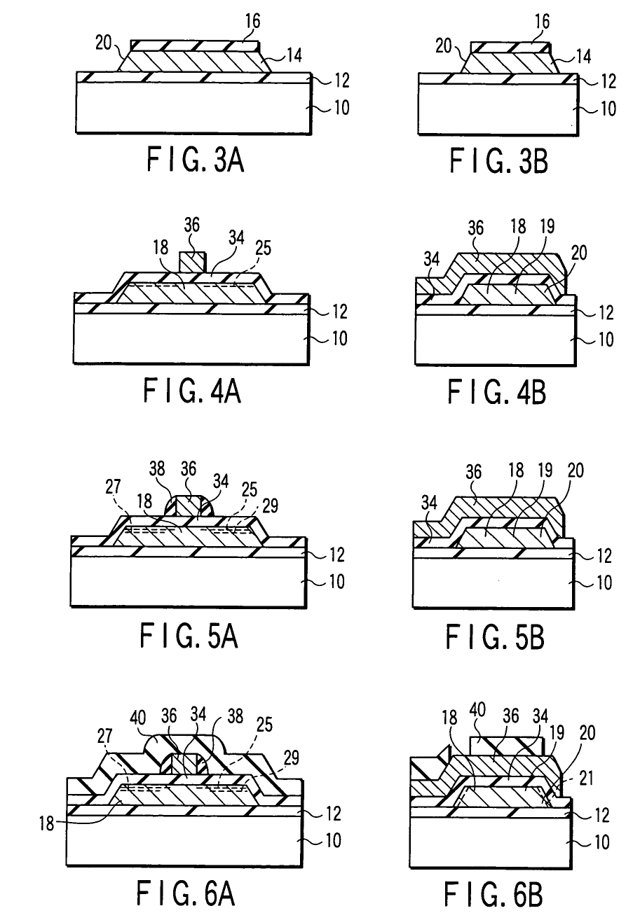

(2) Subsequently, a separation of the semiconductor layer 14 is being carried out in order to form a device region. Specifically, the semiconductor layer 14 is processed by lithography and etching so that a device region is formed as shown in FIGS. 3A and 3B. Although it is preferable for a sidewall of each end of the device region to have a perpendicular shape, the tapered portion 20 is actually formed as described above.

(3) Then, after removing the cap insulator 16 on the semiconductor layer 14, a gate insulator 34 is deposited on the entire surface. It can be used, e.g., an SiO₂ film, an SiN film or a silicon oxynitride film (an SiON film) as the gate insulator 34. Then, an electroconductive film as a material for a gate electrode is deposited on the gate insulator 34. As the gate electrode material, it can be used, e.g., n+ polycrystal silicon in which phosphorous (P), arsenic (As) or the like is doped at a high concentration, or an electroconductive material containing tungsten (W), tantalum (Ta), titanium (Ti) or the like as a main component. The gate electrode material is patterned by lithography and etching, thereby forming the gate electrode 36 (FIGS. 4A and 4B).

(4) Then, an LDD or an extension (which will be referred to as an LDD hereinafter) having a lower impurity concentration than the source and the drain is being formed to improve breakdown voltage characteristics of the thin film transistor. Specifically, n type impurity, e.g., As, is ion-implanted into the semiconductor layer 14 at a low energy with the gate electrode 36 being used as a mask so that doping 25 for forming the LDD is carried out (FIG. 4A).

(5) Further, an insulator 38, e.g., an SiN film, is deposited on the entire surface, and a side wall insulator 38 is formed on each side wall portion of the gate electrode 36 in a self-aligned manner by anisotropic dry etching. With the gate electrode 36 and each side wall insulator 38 being used as a mask, n type impurity, e.g., As with a higher concentration than that of the LDD is ion-implanted into the semiconductor layer 14 at a higher energy so that doping 27 and 29 for forming the source and drain is carried out (FIG. 5A).

(6) Then, the tapered portion 20 of the channel region and the body terminal 32 are being doped. Specifically, an area other than each tapered portion 20 of the channel region and the body terminal 32 (see FIG. 1A) covered with the gate electrode 36 are covered with a mask 40, and p type impurity having a different electroconductive type from that of the source and the drain, e.g., boron (B), is ion-implanted 21 into each tapered portion 20 of the channel and the body terminal 32 (FIGS. 6A and 6B).

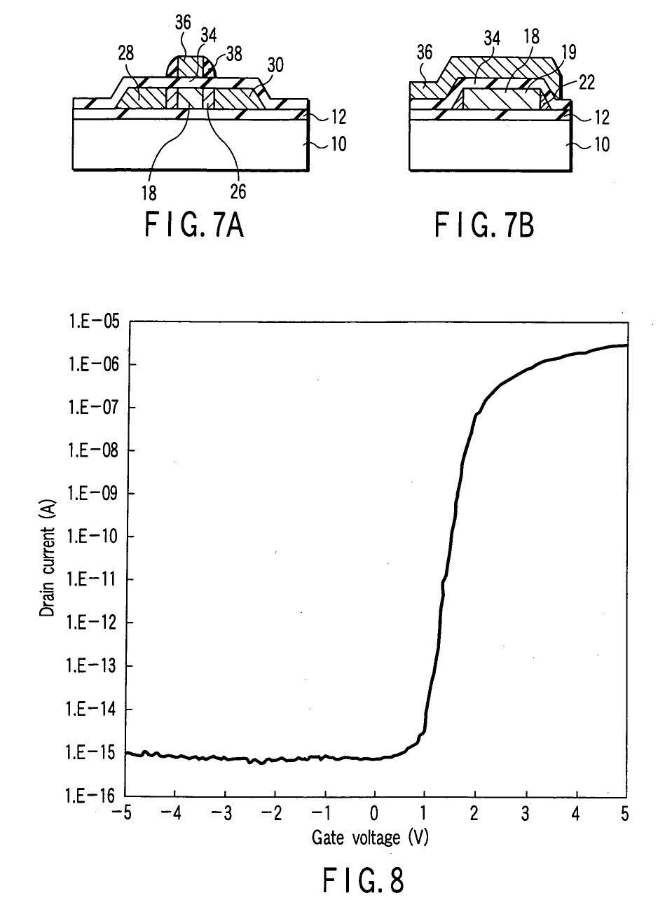

(7) After removing the mask 40, annealing is performed in order to electrically activate the ion-implanted impurities, and the LDD 26, the source 28 and the drain 30, the channel edge portions 22 and 22b and the body terminal 32 are thereby formed (FIGS. 7A and 7B).

Thereafter, a wiring and others are formed, thereby the thin film transistor 3 having the body terminal structure is completed.

The order of steps can be arbitrarily changed as long as the above-described step (6) is set after the step (3) and before the step (7).

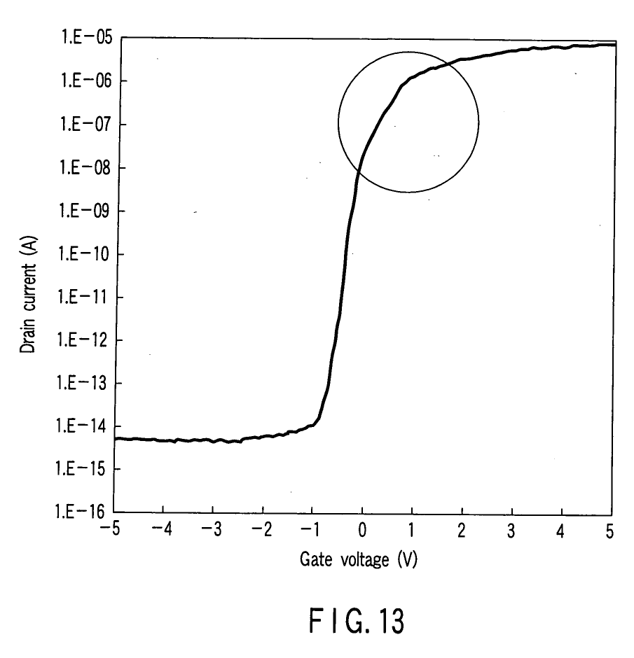

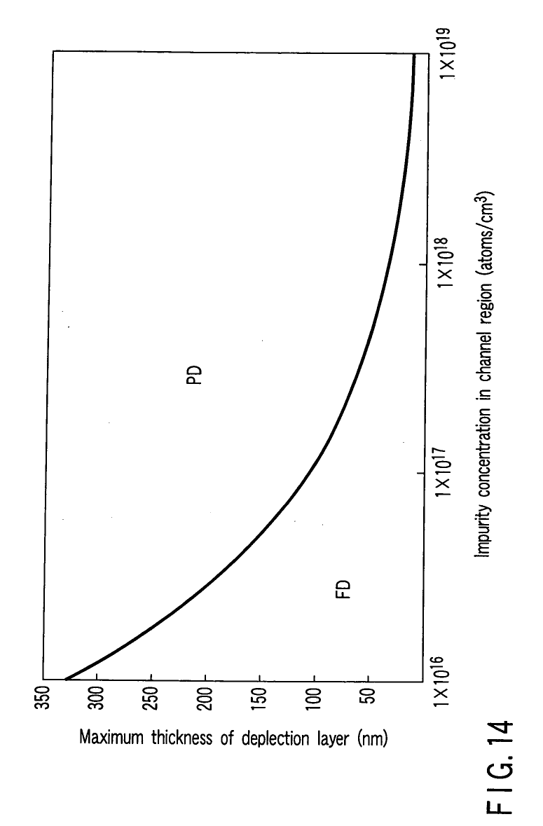

FIG. 8 shows drain current-gate voltage (I-V) characteristics of the thus formed thin film transistor 3. In the drawing, a horizontal axis represents a gate voltage, and a vertical axis represents a drain current. A channel length of the thin film transistor 3 is 2 μm, and an impurity (boron) concentration in the channel region 18 is 1×10¹⁷ atoms/cm³. The impurity in the channel edge portion 22 is boron, and an impurity concentration is 1×10¹⁹ atoms/cm³ which is higher than that of the channel region 18. As apparent from FIG. 8, the “bulge” of the I-V characteristics observed in FIG. 13 does not exist, this means that the thin film transistor 3 having the excellent characteristics can be formed. It owes to effects of doping to channel edge portions 22 and 22b and forming the body terminal 32. When a voltage is applied to the gate electrode 36 and a depletion layer is formed in the flat channel portion 19, due to setting the impurity concentration of the channel edge portions 22 and 22b higher than that of the flat channel portion 19, a depletion layer is hard to be formed in the channel edge portions 22 and 22b, and a substrate potential is stabilized by the body terminal 32. That is, the thin film transistor 3 which is entirely of a partial depletion type can be formed irrespective of the taper angles of the channel edge portions 22 and 22b. Therefore, such a thin film transistor 3 as described above can be formed.

Further, the effect of forming the body terminal 32 also prominently appears in improvement in a source-drain breakdown voltage. Table 1 shows the influence of the body terminal 32 on source-drain breakdown voltages of a partial depletion type transistor and a full depletion type transistor. In an n channel transistor used in the example, the semiconductor layer 14 has a thickness which is 200 nm in case of the partial depletion type and 50 nm in case of the full depletion type, a channel length of the transistor is 2 μn, a channel width is 1 μm, an impurity concentration of the channel region 18 is 1×10¹⁷ atoms/cm³, and an impurity concentration of the channel edge portions 22 and 22b is 1×10¹⁹ atoms/cm³. By providing the body terminal structure, the source-drain breakdown voltage is considerably improved in both the partial depletion type and the full depletion type transistor. In case of the partial depletion type transistor, in particular, the effect is prominent, the source-drain breakdown voltage is lower than that of the full depletion type by 0.8V when the body terminal is not provided, but the source-drain breakdown voltage is improved from 1.4V to 6.2V by providing the body terminal structure, and hence the breakdown voltage becomes higher than that of the full depletion type with body terminal.

TABLE 1

| | Partial | Full |
|---|---|---|
| | depletion | depletion |
| | type | type |
| With body terminal | 6.2 V | 4.6 V |
| Without body terminal | 1.4 V | 2.2 V |

As described above, according to the embodiment, a substrate potential can be controlled, and the substantially entire channel region 18 can be formed as the partial depletion type irrespective of a size of the taper angle of the channel region end portion 20. Thereby producing the thin film transistor in which irregularities in characteristics of the thin film transistor caused due to coexistence of regions with the full depletion type and the partial depletion type, characteristics of the breakdown voltage and others are improved.

### Modification of First Embodiment

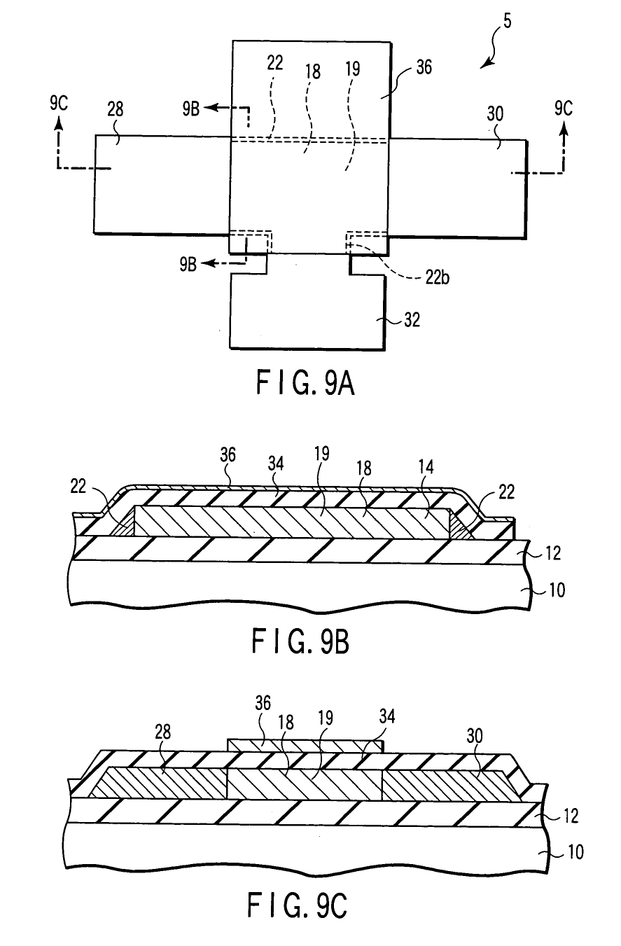

FIGS. 9A, 9B and 9C show a modification of the first embodiment. FIG. 9A is a plan view, FIG. 9B is a cross-sectional view in the channel width direction taken along a cutting plane line 9B-9B in FIG. 9A, and FIG. 9C is a cross-sectional view in the channel length direction taken along a cutting plane line 9C-9C in FIG. 9A. This modification is a thin film transistor 5 in which an LDD or an extension (which will be referred to as an LDD hereinafter) is not formed at ends of a source 28 and a drain 30 near a gate electrode 36. In the modification, the thin film transistor 5 likewise has a body terminal 32, and an electroconductive impurity having different type from that in the source 28 and the drain 30 is doped in channel edge portions 22 and 22b.

The thin film transistor 5 can be formed by eliminating steps for forming the LDD from the first embodiment. That is, step of ion implantation for forming the LDD described in step (4) is eliminated, and step of forming the sidewall insulator 38 described in step (5) can be eliminated.

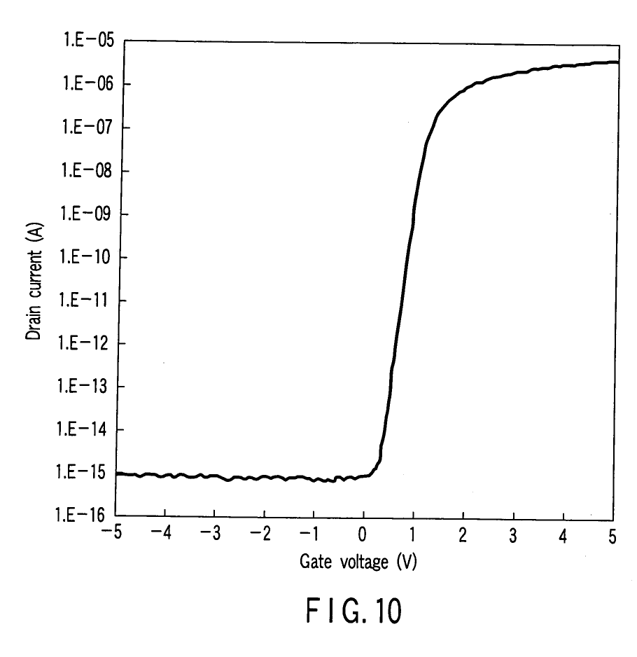

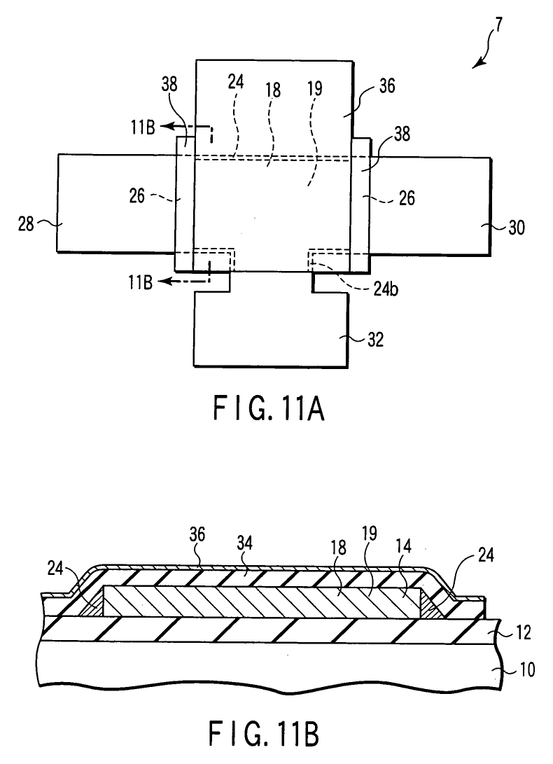

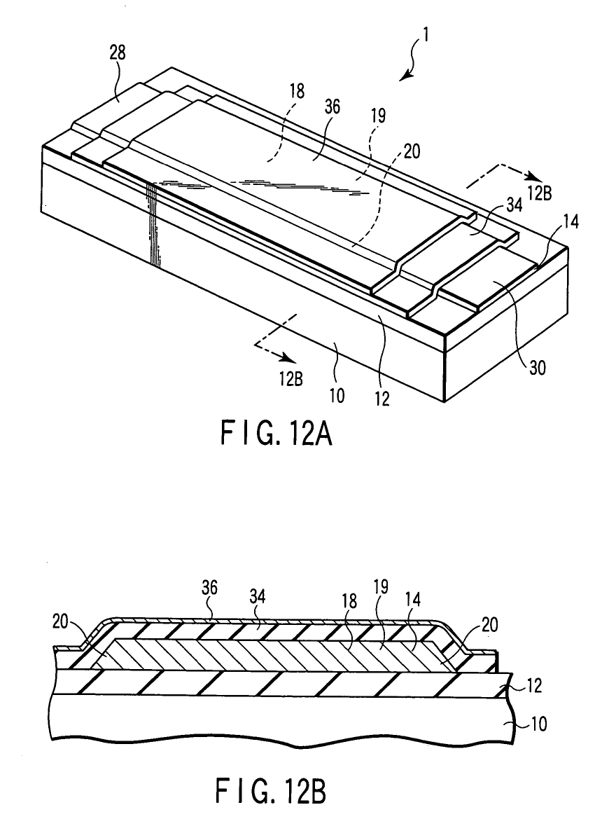

FIG. 10 shows drain current-gate voltage characteristics of the thin film transistor 5 in which the LDD is not formed. In the drawing, a horizontal axis represents a gate voltage, and a vertical axis represents a drain current. An impurity (boron) concentration of a flat channel portion 19 in the thin film transistor 5 is 5×10¹⁶ atoms/cm³, and an impurity (boron) concentration of channel edge portions 22 and 22b is 1×10¹⁹ atoms/cm³ which is higher than that of the flat channel portion 19. As apparent from FIG. 10, the “bulge” of the I-V characteristics is not observed like in FIG. 8, and this means that the thin film transistor 5 having the excellent characteristics is formed. That is, it can be formed the thin film transistor 5 in which the substantially entire channel region 18 is of the partial depletion type irrespective of the taper angles of the channel edge portions 22 and 22b.

The manufacturing process of the first embodiment has been described while taking formation of the n channel type transistor as an example, but a p channel transistor can be formed by just reversing the electroconductive type of the impurity to be doped.

Furthermore, in case of a CMOS device including both an n channel transistor and a p channel transistor, the CMOS device can be formed by performing doping in the channel edge portion as follows without increasing the number of steps. That is, doping into the channel edge portion of the n channel transistor is carried out simultaneously with doping to the LDD or the source/drain of the p channel transistor. Moreover, likewise, doping into the channel edge portion of the p channel transistor is performed simultaneously with doping to the LDD or the source/drain of the n channel transistor. In this manner, the CMOS thin film transistor can be formed without increasing the number of steps.

### Second Embodiment

A second embodiment is, e.g., an n channel thin film transistor 7 in which a channel edge insulating region 24 where a tapered portion 20 is electrically inactive is formed by considerably increasing a resistivity of the tapered portion 20. FIGS. 11A and 11B show an example of the embodiment. FIG. 11A is a plan view, and FIG. 11B is a cross-sectional view in a channel width direction taken along a cutting plane line 11B-11B in FIG. 11A. In the embodiment, the thin film transistor 7 likewise has a body terminal 32 which is used to control a substrate potential.

The thin film transistor 7 according to the embodiment can be formed by changing doping of the impurity in the tapered portion 20 described at the step (6) in the first embodiment as follows. It is to be noted that doping into the body terminal 32 is performed separately from processing with respect to the tapered portion 20.

(6-1) Regions other than a tapered portion 20 of a channel region 18 are covered with a mask, and an impurity which considerably increases a resistivity of the tapered portion 20 is introduced. For example, an impurity such as oxygen or nitrogen is ion-implanted in order to form a channel edge insulating region 24. Alternatively, in order to increase a resistivity by compensating carriers in the channel edge portion 24, an electroconductive impurity having different type from that in the p type channel region 18, e.g., an n type impurity such as phosphorous (P) is ion-planted as much as substantially the same number of carriers as a carrier concentration of the channel area 18 can be generated.

(6-2) Then, regions other than the body terminal 32 are covered with a mask, and an electroconductive impurity having different type from that in the source 28 and the drain 30, e.g., a p type impurity such as boron (B) is ion-implanted into the body terminal 32 portion.

In the embodiment, like the first embodiment, doping into the source 28 and the drain 30 described in step (5) in the first embodiment, introduction of the impurity into the channel edge insulating region 24 described in (6-1) and doping into the body terminal 32 described in (6-2) can be carried out in any order.

As to the characteristics of the thin film transistor 7 formed in accordance with the embodiment, like the first embodiment, it can be confirmed that a substrate potential can be controlled, the “bulge” of the gate voltage-drain current characteristics is eliminated and a source-drain breakdown voltage is also improved.

The present invention can be also achieved by the following semiconductor apparatus manufacturing methods.

A semiconductor apparatus manufacturing method according to a first aspect comprises: forming a device region having a first electroconductive type by patterning a semiconductor film formed on one surface side of a substrate; forming a gate insulator on the device region; forming a gate electrode on the gate insulator by covering a part of the device region; forming a low-concentration diffusion region having a second electroconductive type in the device region adjacent to an outer side of the gate electrode; forming a high-concentration diffusion region having the second electroconductive type in the device region adjacent to an outer side of the low-concentration diffusion region; forming a body terminal having the first electroconductive type in the device region on the outer side of the gate electrode which is also a region different from the low-concentration diffusion region and the high-concentration diffusion region; and adding an impurity having the first electroconductive type into an end portion of the device region covered with the gate electrode which is a region excluding a part in contact with the low-concentration diffusion region and body terminal.

A semiconductor apparatus manufacturing method according to a second aspect comprises: forming a first device region having a first electroconductive type by patterning a semiconductor film formed on one surface side of a substrate; forming a first gate insulator on the first device region; forming a first gate electrode on the first gate insulator by covering a part of the first device region; forming a first high-concentration diffusion region having a second electroconductive type in the first device region adjacent to an outer side of the first gate electrode; forming a first body terminal having the first electroconductive type in the first device region on the outer side of the first gate electrode which is also a region different from the first high-concentration diffusion region; forming a first semiconductor device by adding an impurity having the first electroconductive type into an end portion of the first device region covered with the first gate electrode which is also excluding a region in contact with the first high-concentration diffusion region and first body terminal; forming a second device region having the second electroconductive type by patterning the semiconductor film; forming a second gate insulator on the second device region; forming a second gate electrode on the second gate insulator by covering a part of the second device region; forming a second high-concentration diffusion region having the first electroconductive type in the second device region adjacent to an outer side of the second gate electrode; forming a second body terminal having the second electroconductive type in the second device region on the outer side of the second gate electrode which is also a region different from the second high-concentration diffusion region; and forming a second semiconductor device by adding an impurity having the second electroconductive type into an end portion of the second device region covered with the second gate electrode which is also excluding a region in contact with the second high-concentration diffusion region and second body terminal.

A semiconductor apparatus manufacturing method according to a third aspect comprises: forming a first device region having a first electroconductive type by patterning a semiconductor film formed on one surface side of a substrate; forming a first gate insulator on the first device region; forming a first gate electrode on the first gate insulator by covering a part of the first device region; forming a first low-concentration diffusion region having a second electroconductive type in the first device region adjacent to an outer side of the first gate electrode; forming a first high-concentration diffusion region having the second electroconductive type in the first device region adjacent to an outer side of the first low-concentration diffusion region; forming a first body terminal having the first electroconductive type in the first device region on the outer side of the first gate electrode which is also a region different from the first low-concentration diffusion region and the first high-concentration diffusion region; forming a first semiconductor device by adding an impurity having the first electroconductive type into an end portion of the first device region covered with the first gate electrode which is also excluding a region in contact with the first high-concentration diffusion region and first body terminal; forming a second device region having the second electroconductive type by patterning the semiconductor film; forming a second gate insulator on the second device region; forming a second gate electrode on the second gate insulator by covering a part of the second device region; forming a first electroconductive type second low-concentration diffusion region in the second device region adjacent to an outer side of the second gate electrode; forming a second low-concentration diffusion region having the first electroconductive type in the second device region adjacent to an outer side of the second gate electrode; forming a second high-concentration diffusion region having the first electroconductive type in the second device region adjacent to an outer side of the second low-concentration diffusion region; forming a second body terminal having the second electroconductive type in the second device region on the outer side of the second gate electrode which is also a region different from the second low-concentration diffusion region and the second high-concentration diffusion region; and forming a second semiconductor device by adding an impurity having the second electroconductive type into an end portion of the second device region covered with the second gate electrode which is also excluding a region in contact with the second high-concentration diffusion region and second body terminal.

The semiconductor apparatus manufacturing method according to the third aspect can also be characterized in that an impurity concentration of a channel edge portion of the first semiconductor device is substantially equal to an impurity concentration of the second low-concentration diffusion region of the second semiconductor device, and an impurity concentration of a channel edge portion of the second semiconductor device is substantially equal to an impurity concentration of the first low-concentration diffusion region of the first semiconductor device.

The semiconductor apparatus manufacturing method according to the second and third aspects can also be characterized in that an impurity concentration of a channel edge portion of the first semiconductor device is substantially equal to an impurity concentration of the second high-concentration diffusion region of the second semiconductor device, and an impurity concentration of a channel edge portion of the second semiconductor device is substantially equal to an impurity concentration of the first high-concentration diffusion region of the first semiconductor device.

As described above, according to various embodiments of the present invention, it can be provide a thin film transistor in which a substrate potential of the thin film transistor can be controlled, the substantially entire channel region can be formed as the partial depletion type irrespective of a size of a taper angle of the channel region end portion, and irregularities in characteristics caused due to coexistence of the full depletion type and the partial depletion type region, characteristics in breakdown voltage and others are improved.

The above description on the embodiments disclosed herein is given to enable any person who has the knowledge in this field to create or use the present invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. A semiconductor apparatus comprising:
a semiconductor layer provided on one surface side of a substrate;
a channel region having a first electroconductive type provided in the semiconductor layer;
a high-concentration diffusion region having a second electroconductive type provided in the semiconductor layer being adjacent to the channel region, facing both sides of the channel region, and being separated;
a body terminal having the first electroconductive type which is connected with the channel region to fix a potential of the channel region;
an insulator provided on the channel region;
a gate electrode provided on the insulator to cover the channel region; and
a channel edge portion disposed at an end portion of the channel region and also at an end portion of the semiconductor layer, and containing an impurity having the first electroconductive type therein.

2. The semiconductor apparatus according to claim 1, wherein the semiconductor apparatus is substantially a partial depletion type semiconductor apparatus.

3. The semiconductor apparatus according to claim 1, wherein an impurity concentration of the channel edge portion is tenfold or more of an impurity concentration of the channel region.

4. The semiconductor apparatus according to claim 3, wherein the semiconductor apparatus is substantially a partial depletion type semiconductor apparatus.

5. A semiconductor apparatus comprising:
a semiconductor layer provided on one surface side of a substrate;
a channel region having a first electroconductive type provided in the semiconductor layer;
a low-concentration diffusion region having a second electroconductive type provided in the semiconductor layer being adjacent to the channel region, facing both sides of the channel region, and being separated;
a high-concentration diffusion region having the second electroconductive type provided in the semiconductor layer on an outer side of each low-concentration diffusion region;
a body terminal having the first electroconductive type which is connected with the channel region to fix a potential of the channel region;
an insulator provided on the channel region;
a gate electrode provided on the insulator to cover the channel region; and
a channel edge portion disposed at an end portion of the channel region and also at an end portion of the semiconductor layer, and containing an impurity having the first electroconductive type therein.

6. The semiconductor apparatus according to claim 5, wherein the semiconductor apparatus is substantially a partial depletion type semiconductor apparatus.

7. The semiconductor apparatus according to claim 5, wherein an impurity concentration of the channel edge portion is tenfold or more of an impurity concentration of the channel region.

8. The semiconductor apparatus according to claim 7, wherein the semiconductor apparatus is substantially a partial depletion type semiconductor apparatus.

9. A semiconductor apparatus comprising:
a semiconductor layer provided on one surface side of a substrate; and
first and second semiconductor devices provided in the semiconductor layer,
the first semiconductor device comprising:
a first channel region having a first electroconductive type provided in the semiconductor layer;
a first high-concentration diffusion region having a second electroconductive type provided in the semiconductor layer being adjacent to the first channel region, facing both sides of the channel region, and being separated;
a first body terminal having a first electroconductive type which is connected with the first channel region to fix a potential of the first channel region;
a first insulator provided on the first channel region;
a first gate electrode provided on the first insulator to cover the first channel region; and
a first channel edge portion disposed at an end portion of the first channel region and also at an end portion of the semiconductor layer, and containing an impurity having the first electroconductive type therein, the second semiconductor device comprising:
a second channel region having the second electroconductive type provided in the semiconductor layer;
a second high-concentration diffusion region having the first electroconductive type provided in the semiconductor layer being adjacent to the second channel region, facing both sides of the channel region, and being separated;
a second body terminal having the second electroconductive type which is connected with the second channel region to fix a potential of the second channel region;
a second insulator provided on the second channel region;
a second gate electrode which is provided on the second insulator and covers the second channel region; and
a second channel edge portion disposed at an end portion of the second channel region and also at an end portion of the semiconductor layer, and containing an impurity having the second electroconductive type therein.

10. The semiconductor apparatus according to claim 9, wherein the semiconductor apparatus is substantially a partial depletion type semiconductor apparatus.

11. The semiconductor apparatus according to claim 9, wherein an impurity concentration of the first channel edge portion in the first semiconductor device is substantially equal to an impurity concentration of the second high-concentration diffusion region in the second semiconductor device, and
an impurity concentration of the second channel edge portion in the second semiconductor device is substantially equal to an impurity concentration of the first high-concentration diffusion region in the first semiconductor device.

12. The semiconductor apparatus according to claim 11, wherein the semiconductor apparatus is substantially a partial depletion type semiconductor apparatus.

13. A semiconductor apparatus comprising:
a semiconductor layer provided on one surface side of a substrate; and
first and second semiconductor devices provided in the semiconductor layer,
the first semiconductor device comprising:
a first channel region having a first electroconductive type provided in the semiconductor layer;
a first low-concentration diffusion region having a second electroconductive type provided in the semiconductor layer being adjacent to the first channel region, facing both sides of the first channel region, and being separated;
a first high-concentration diffusion region having the second electroconductive type provided in the semiconductor layer on an outer side of each first low-concentration diffusion region;
a first body terminal having a first electroconductive type connected with the first channel region to fix a potential of the first channel region;
a first insulator provided on the first channel region;
a first gate electrode provided on the first insulator to cover the first channel region; and
a first channel edge portion disposed at an end portion of the first channel region and also at an end portion of the semiconductor layer, and containing an impurity having the first electroconductive type therein, the second semiconductor device comprising:
a second channel region having the second electroconductive type provided in the semiconductor layer;
a second low-concentration diffusion region having the first electroconductive type provided in the semiconductor layer being adjacent to the second channel region, facing both sides of the second channel region, and being separated;
a second high-concentration diffusion region having the first electroconductive type provided in the semiconductor layer on an outer side of each second low-concentration diffusion region;
a second body terminal having the second electroconductive type which is connected with the second channel region to fix a potential of the second channel region;
a second insulator provided on the second channel region;
a second gate electrode which is provided on the second insulator and covers the second channel region; and
a second channel edge portion disposed at an end portion of the second channel region and also at an end portion of the semiconductor layer, and containing an impurity having the second electroconductive type therein.

14. The semiconductor apparatus according to claim 13, wherein the semiconductor apparatus is substantially a partial depletion type semiconductor apparatus.

15. The semiconductor apparatus according to claim 13, wherein an impurity concentration of the first channel edge portion in the first semiconductor device is substantially equal to an impurity concentration of the second low-concentration diffusion region in the second semiconductor device, and
an impurity concentration of the second channel edge portion in the second semiconductor device is substantially equal to an impurity concentration of the first low-concentration diffusion region in the first semiconductor device.

16. The semiconductor apparatus according to claim 15, wherein the semiconductor apparatus is substantially a partial depletion type semiconductor apparatus.

17. The semiconductor apparatus according to claim 13, wherein an impurity concentration of the first channel edge portion in the first semiconductor device is substantially equal to an impurity concentration of the second high-concentration diffusion region in the second semiconductor device, and
an impurity concentration of the second channel edge portion in the second semiconductor device is substantially equal to an impurity concentration of the first high-concentration diffusion region in the first semiconductor device.

18. The semiconductor apparatus according to claim 17, wherein the semiconductor apparatus is substantially a partial depletion type semiconductor apparatus.

19. A semiconductor apparatus comprising:
a semiconductor layer provided on one surface side of a substrate;
a channel region having a first electroconductive type provided in the semiconductor layer;
a high-concentration diffusion region having a second electroconductive type provided in the semiconductor layer being adjacent to the channel region, facing both sides of the channel region, and being separated;
a body terminal having the first electroconductive type which is connected with the channel region to fix a potential of the channel region;
an insulator provided on the channel region;
a gate electrode provided on the insulator to cover the channel region; and
a channel edge portion disposed at an end portion of the channel region and also at an end portion of the semiconductor layer, and being substantially insulative.

20. The semiconductor apparatus according to claim 19, wherein the semiconductor apparatus is substantially a partial depletion type semiconductor apparatus.

21. A semiconductor apparatus comprising:
a semiconductor layer provided on one surface side of a substrate;
a channel region having a first electroconductive type provided in the semiconductor layer;
a low-concentration diffusion region having a second electroconductive type provided in the semiconductor layer being adjacent to the channel region, facing both sides of the channel region, and being separated;
a high-concentration diffusion region having the second electroconductive type provided in the semiconductor layer on an outer side of each low-concentration diffusion region;
a body terminal having the first electroconductive type which is connected with the channel region to fix a potential of the channel region;
an insulator provided on the channel region;
a gate electrode provided on the insulator to cover the channel region; and
a channel edge portion disposed at an end portion of the channel region and also at an end portion of the semiconductor layer, and being substantially insulative.

22. The semiconductor apparatus according to claim 21, wherein the semiconductor apparatus is substantially a partial depletion type semiconductor apparatus.

23. A semiconductor apparatus manufacturing method comprising:
forming a device region having a first electroconductive type by patterning a semiconductor film formed on one surface side of a substrate;
forming a gate insulator on the device region;
forming a gate electrode on the gate insulator by covering a part of the device region;
forming a high-concentration diffusion region having a second electroconductive type in the device region adjacent to an outer side of the gate electrode;
forming a body terminal having the first electroconductive type in the device region on the outer side of the gate electrode which is also a region different from the low-concentration diffusion region and the high-concentration diffusion region; and
adding an impurity having the first electroconductive type into an end portion of the device region covered with the gate electrode which is a region excluding a part in contact with the high-concentration diffusion region and body terminal.
